(19) United States
(12) Patent Application Publication
(10) Pub. No.: US 2025/0287721 A1
(43) Pub. Date: Sep. 11, 2025

(54) SEMICONDUCTOR LIGHT-RECEIVING ELEMENT

(71) Applicant: HAMAMATSU PHOTONICS K.K., Hamamatsu-shi, Shizuoka (JP)

(72) Inventors: Keiki TAGUCHI, Hamamatsu-shi, Shizuoka (JP); Hajime ISHIHARA, Hamamatsu-shi, Shizuoka (JP)

(73) Assignee: HAMAMATSU PHOTONICS K.K., Hamamatsu-shi, Shizuoka (JP)

(21) Appl. No.: 18/860,184

(22) PCT Filed: Jan. 19, 2023
(86) PCT No.: PCT/JP2023/001523

§ 371 Date: Oct. 25, 2024

(30) Foreign Application Priority Data
May 13, 2022 (JP) 2022-079384

(51) Int. Cl. H10F 77/124; H10F 30/10

(52) U.S. Cl. CPC H10F 77/1248; H10F 30/10

(57) ABSTRACT

A semiconductor light receiving element includes: a front surface that receives incident light; a first semiconductor layer of a first conductivity type; a second semiconductor layer of the first conductivity type stacked on the first semiconductor layer on the front surface side of the first semiconductor layer and having a band gap energy larger than a band gap energy of the first semiconductor layer; and a doped region formed so as to extend from the front surface toward the second semiconductor layer and reach at least an inside of the second semiconductor layer and having a second conductivity type different from the first conductivity type. A thickness of the second semiconductor layer in a first direction intersecting the front surface is smaller than a thickness of the first semiconductor layer in the first direction.

### TECHNICAL FIELD

The present disclosure relates to a semiconductor light receiving element.

### BACKGROUND ART

Patent Literature 1 describes a light receiving element. This light receiving element includes a light absorption layer that absorbs incident light and converts the incident light into an electrical signal, a cap layer that is formed on the light incidence side of the light absorption layer and has a larger energy band gap than the light absorption layer, and a contact layer that is formed around the light receiving surface of the cap layer, is formed of the same material as the light absorption layer, and is thicker than the cap layer. In addition, in this light receiving element, a P⁺-type high-concentration impurity region is formed by doping impurities at a high concentration in the vicinity of the interface between the light absorption layer and the cap layer and in the cap layer and the contact layer.

### CITATION LIST

### Patent Literature

Patent Literature 1: Japanese Unexamined Patent Publication No. 2001-177142

### SUMMARY OF INVENTION

### Technical Problem

In the light receiving element described in Patent Literature 1, it can be seen that the high-concentration impurity region is formed over the entire light receiving surface of the light absorption layer and the cap layer. In this case, since light having a wavelength that is absorbed in the high-concentration impurity region cannot be extracted as a signal, a loss may occur to decrease sensitivity.

It is an object of the present disclosure to provide a semiconductor light receiving element capable of suppressing a decrease in sensitivity.

### Solution to Problem

A semiconductor light receiving element according to the present disclosure is [1] “a semiconductor light receiving element including: a front surface that receives incident light; a first semiconductor layer of a first conductivity type; a second semiconductor layer of the first conductivity type stacked on the first semiconductor layer on the front surface side of the first semiconductor layer and having a band gap energy larger than a band gap energy of the first semiconductor layer; and a doped region formed so as to extend from the front surface toward the second semiconductor layer side and reach at least an inside of the second semiconductor layer and having a second conductivity type different from the first conductivity type, wherein a thickness of the second semiconductor layer in a first direction intersecting the front surface is smaller than a thickness of the first semiconductor layer in the first direction, the doped region includes a plurality of parts facing each other with a gap interposed therebetween when viewed from the first direction, and a width of the gap is larger than a thickness of the second semiconductor layer in the first direction”.

In the semiconductor light receiving element of [1] above, a second semiconductor layer of the first conductivity type having a large band gap energy is stacked on a first semiconductor layer of a first conductivity type, and a doped region of the second conductivity type is formed extending from the front surface that receives incident light toward the second semiconductor layer side. Then, the doped region includes a plurality of parts that face each other with a gap therebetween when viewed from a first direction intersecting the front surface. Therefore, light incident on the gap between the doped regions can be extracted as a signal without being absorbed in the doped regions. Therefore, the decrease in sensitivity is suppressed. In particular, according to the findings of the present inventors, when the width of the gap is larger than the thickness of the second semiconductor layer, the decrease in sensitivity can be further suppressed.

The semiconductor light receiving element according to the present disclosure may be [2] “the semiconductor light receiving element according to [1] above, wherein the plurality of parts of the doped region include at least a pair of extending portions extending in the same direction when viewed from the first direction and the width of the gap is a distance between the pair of extending portions”. According to the semiconductor light receiving element described in [2], a structure capable of suppressing a decrease in sensitivity can be easily and reliably formed.

The semiconductor light receiving element according to the present disclosure may be [3] “the semiconductor light receiving element according to [1] or [2] above, wherein the doped region extends from the second semiconductor layer toward the first semiconductor layer side and reaches an inside of the first semiconductor layer”. According to the semiconductor light receiving element described in [3], the doped region may be formed in this manner.

The semiconductor light receiving element according to the present disclosure may be [4] “the semiconductor light receiving element according to any one of [1] to [3] above, wherein a recess is formed on the front surface and a light receiving portion is formed in a region overlapping a bottom surface of the recess when viewed from the first direction”. According to the semiconductor light receiving element described in [4], a region corresponding to the bottom surface of the recess is a light receiving portion. This protects the light receiving portion from contact and makes it less susceptible to damage.

The semiconductor light receiving element according to the present disclosure may be [5] “the semiconductor light receiving element according to [4] above, wherein the doped region is exposed on a side surface of the recess”. According to the semiconductor light receiving element described in [5], it is possible to extract, as a signal, even light incident on the gap between a part of the doped region exposed on the side surface of the recess and a part facing the part. As a result, the decrease in sensitivity can be more reliably suppressed. In addition, in this case, the doped region includes a part formed from the side surface of the recess to the top surface (a region that defines the recess on the front surface) of the recess. This part has a part, which is thicker and has a higher impurity concentration than the part formed on the bottom surface side of the recess in the doped region, on the front surface side. Therefore, it is possible to reduce the contact resistance by making contact with the electrode at this part.

The semiconductor light receiving element according to the present disclosure may be [6] “the semiconductor light receiving element according to any one of [1] to [5] above, further including a third semiconductor layer of the first conductivity type stacked on the second semiconductor layer on the front surface side of the second semiconductor layer”. According to the semiconductor light receiving element described in [6], by using a material having a larger band gap energy than the first semiconductor layer and the third semiconductor layer as the second semiconductor layer, it is possible to reduce the dark current and absorption, thereby achieving a further reduction in loss.

The semiconductor light receiving element according to the present disclosure may be [7] “the semiconductor light receiving element according to [6] above, further including a fourth semiconductor layer of the first conductivity type stacked on the third semiconductor layer on the front surface side of the third semiconductor layer”. According to the semiconductor light receiving element described in [7], since the fourth semiconductor layer has a function of protecting the third semiconductor layer, it is possible to select a material of the third semiconductor layer that contains a material that is relatively easily oxidized, such as aluminium, thereby improving the freedom of material selection for the third semiconductor layer.

The semiconductor light receiving element according to the present disclosure may be [8] “the semiconductor light receiving element according to any one of [1] to [7] above, wherein the first semiconductor layer contains InGaAs, and the second semiconductor layer contains InP or InAsP”.

The semiconductor light receiving element according to the present disclosure may be [9] “the semiconductor light receiving element according to [6] or [7] above, wherein the first semiconductor layer contains InAsSb or InAs, the second semiconductor layer contains AlInAsSb, and the third semiconductor layer contains InAsSb or InPSb”.

The semiconductor light receiving element according to the present disclosure may be “the semiconductor light receiving element according to [7] above, wherein the first semiconductor layer contains InGaAs, the second semiconductor layer contains InP or InAsP, the third semiconductor layer contains InGaAs, and the fourth semiconductor layer contains InP or InAsP”.

### Advantageous Effects of Invention

According to the present disclosure, it is possible to provide a semiconductor light receiving element capable of suppressing a decrease in sensitivity.

### BRIEF DESCRIPTION OF DRAWINGS

FIG. 1 is a schematic drawing showing a semiconductor light receiving element according to the present embodiment.

FIG. 2 is a drawing showing an operation of the semiconductor light receiving element shown in FIG. 1.

FIG. 3 is a drawing showing a step of a method for manufacturing a semiconductor light receiving element.

FIG. 4 is a drawing showing a step of the method for manufacturing a semiconductor light receiving element.

FIG. 5 is a drawing showing a step of the method for manufacturing a semiconductor light receiving element.

FIG. 6 is a schematic cross-sectional view of a semiconductor light receiving element according to a modification example.

FIG. 7 is a schematic plan view of a semiconductor light receiving element according to a modification example.

FIG. 8 is a schematic plan view of a semiconductor light receiving element according to a modification example.

### DESCRIPTION OF EMBODIMENTS

Hereinafter, a semiconductor light receiving element according to an embodiment will be described with reference to the drawings. In the description of each drawing, the same or corresponding elements are denoted by the same reference numerals, and repeated description thereof may be omitted. In addition, each drawing may show a Cartesian coordinate system defined by the X axis, the Y axis, and the Z axis.

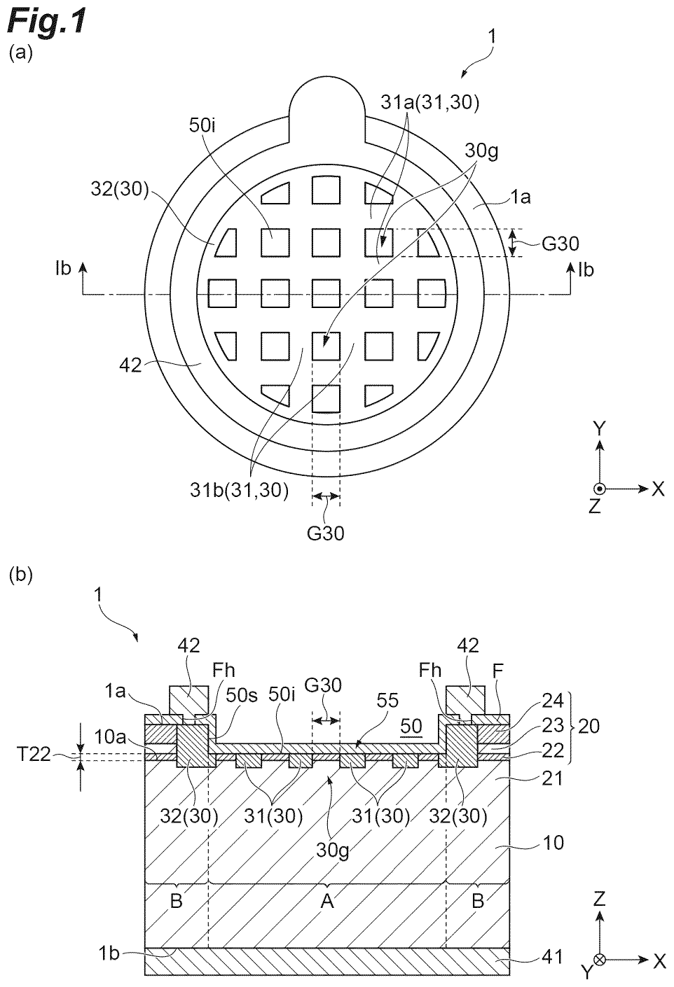

FIG. 1 is a schematic drawing showing a semiconductor light receiving element according to the present embodiment. (a) in FIG. 1 is a plan view, and (b) in FIG. 1 is a cross-sectional view taken along the line Ib-Ib in FIG. 1. As shown in FIG. 1, a semiconductor light receiving element 1 includes a first semiconductor portion 10, a second semiconductor portion 20, electrodes 41 and 42, and a protective film F. The semiconductor light receiving element 1 has a front surface 1a and a back surface 1b opposite to the front surface 1a. In the semiconductor light receiving element 1, for example, the front surface 1a is a light incidence surface. The first semiconductor portion 10 includes the back surface 1b, and the second semiconductor portion 20 includes the front surface 1a. That is, the second semiconductor portion 20 is stacked on the first semiconductor portion 10 on the front surface 1a side.

The first semiconductor portion 10 includes a plurality of semiconductor layers stacked along a first direction (here, the Z-axis direction) intersecting the front surface 1a. The plurality of semiconductor layers include, for example, a substrate (not shown), a buffer layer (not shown), and a light absorption layer (first semiconductor layer) 21, which are stacked in this order from the back surface 1b side.

The substrate is formed of, for example, InP of a first conductivity type (for example, n⁺-type). The buffer layer is formed of, for example, InP of the first conductivity type (for example, n⁺-type or n-type). As an example, the buffer layer has a thickness of about 0.5 to 2.0 μm in the first direction. The light absorption layer 21 contains InGaAs (is formed of InGaAs) of the first conductivity type, for example. As an example, the light absorption layer 21 has a thickness in the first direction of about 1.5 to 5 μm.

The second semiconductor portion 20 includes a first cap layer (second semiconductor layer) 22, a semiconductor layer (third semiconductor layer) 23, and a second cap layer (fourth semiconductor layer) 24, which are stacked in this order from the first semiconductor portion 10 side along the first direction. The first cap layer 22 is stacked on the light absorption layer 21 on the front surface 1a side of the light absorption layer 21, and has an interface with the light absorption layer 21. The semiconductor layer 23 is stacked on the first cap layer 22 on the front surface 1a side of the first cap layer 22, and has an interface with the first cap layer 22. The second cap layer 24 is stacked on the semiconductor layer 23 on the front surface 1a side of the semiconductor layer 23, and has an interface with the semiconductor layer 23.

The first cap layer 22 has a band gap energy larger than the band gap energies of the light absorption layer 21 and the semiconductor layer 23. The first cap layer 22 contains InP (is formed of InP) of the first conductivity type (for example, n-type), for example. As an example, the first cap layer 22 has a thickness T22 of about 0.1 μm in the first direction. The thickness T22 of the first cap layer 22 in the first direction is smaller than the thickness of the light absorption layer 21 in the first direction. The semiconductor layer 23 contains InGaAs (is formed of InGaAs) of the first conductivity type (for example, n-type), for example. As an example, the semiconductor layer 23 has a thickness of about 0.05 to 0.3 μm in the first direction. The second cap layer 24 contains InP (is formed of InP) of the first conductivity type (for example, n-type), for example. As an example, the second cap layer 24 has a thickness of about 0.2 to 2.0 μm in the first direction.

Here, a recess 50 is formed on the front surface 1a. As an example, the front surface 1a has a circular shape when viewed from the first direction (that is, the outer shape of the semiconductor light receiving element 1 is circular), and the recess 50 has a circular shape concentric with the front surface 1a when viewed from the first direction. The recess 50 includes a bottom surface 50i and a side surface 50s connecting the bottom surface 50i and the front surface 1a to each other. The recess 50 penetrates the second cap layer 24 and the semiconductor layer 23. Therefore, the first cap layer 22 is exposed on the bottom surface 50i of the recess 50 (that is, the front surface of the first cap layer 22 forms the bottom surface 50i).

In other words, the first semiconductor portion 10 and the second semiconductor portion 20 include a first region A overlapping the bottom surface 50i of the recess 50 when viewed from the first direction and a second region B outside the first region A, and the semiconductor layer 23 and the second cap layer 24 are formed only in the second region B outside the recess 50. In the semiconductor light receiving element 1, the first region A overlapping the bottom surface 50i of the recess 50 when viewed from the first direction is formed relatively thin, and serves as a light receiving portion 55 that receives incident light and generates an electrical signal.

The protective film F is provided so as to cover the front surface 1a, the side surface 50s of the recess 50, and the bottom surface 50i of the recess 50. The protective film F may have a function as an anti-reflection film. A through hole Fh is formed in the protective film F on the second region B, and the second cap layer 24 is exposed from the through hole Fh. The electrode 41 is formed on the back surface 1b and is in contact with the first semiconductor portion 10 (for example, a substrate). The electrode 42 is formed on the protective film F and is in contact with the second cap layer 24 through the through hole Fh.

The semiconductor light receiving element 1 includes a doped region 30. The doped region 30 is a region of a second conductivity type (for example, p-type) formed by doping the second semiconductor portion 20 and the first semiconductor portion 10 with impurities (for example, Zn). The doped region 30 may be, for example, a diffusion region formed by doping impurities from the front surface 1a side by thermal diffusion. Alternatively, the doped region 30 may be formed by doping impurities using an ion implantation method. The doped region 30 is formed so as to extend from the front surface 1a toward the first cap layer 22 side and reach at least the inside of the first cap layer 22. Here, the doped region 30 extends from the first cap layer 22 toward the light absorption layer 21 side and reaches the inside of the light absorption layer 21.

More specifically, in the first region A, the doped region 30 is formed in the first cap layer 22 and a part of the light absorption layer 21 on the first cap layer 22 side, and in the second region B, the doped region 30 is formed in the second cap layer 24, the semiconductor layer 23, the first cap layer 22, and a part of the light absorption layer 21 on the first cap layer 22 side. The through hole Fh of the protective film F is formed on the doped region 30, and the electrode 42 is in contact with the doped region 30 in the second cap layer 24 (is electrically connected to the doped region 30).

The doped region 30 includes a plurality of parts 31 facing each other when viewed from the first direction. A gap 30g is interposed between the parts 31 facing each other. The width G30 of the gap 30g is larger than the thickness T22 of the first cap layer 22. The plurality of parts 31 include a group (at least one pair) of first extending portions 31a that extend in the same direction and another group (at least one pair) of second extending portions 31b that extend in the same direction but in a direction different from the first extending portions 31a. Here, the first extending portion 31a extends along the X-axis direction, and the second extending portion 31b extends along the Y-axis direction.

The gap 30g is a gap between the first extending portions 31a adjacent to each other and a gap between the second extending portions 31b adjacent to each other. In the present embodiment, the width of the gap between the first extending portions 31a and the width of the gap between the second extending portions 31b are approximately the same. However, when these are different, the smaller one can be set as a width G30 and can be made larger than the thickness T22 of the first cap layer 22. In addition, when the width G30 changes along the extending direction of the first extending portion 31a or the second extending portion 31b, the minimum value or average value thereof can be made larger than the thickness T22.

The first extending portions 31a and the second extending portions 31b are arranged in a lattice pattern by intersecting each other. The first extending portion 31a and the second extending portion 31b are integrated by being connected to the outer edge portion 32 of the doped region 30 at their both ends in the extending direction. Here, the electrode 42 is provided in contact with the outer edge portion 32, so that the first extending portion 31a and the second extending portion 31b are also electrically connected to the electrode 42.

The outer edge portion 32 is formed across the boundary between the first region A and the second region B. That is, the outer edge portion 32 includes a relatively thick part located outside the recess 50 and a relatively thin part located inside the recess 50. Therefore, the outer edge portion 32 is exposed on the side surface 50s of the recess 50 (forms the side surface 50s). That is, the doped region 30 is exposed on the side surface 50s of the recess 50.

In this manner, in the semiconductor light receiving element 1, since the doped region 30 includes a plurality of parts 31 of the second conductivity type that face each other with the gap 30g interposed therebetween when viewed from the first direction, and a PD (Photo Diode) is formed between each of the plurality of parts 31 and a semiconductor region of the first conductivity type (mainly the light absorption layer 21 and the first cap layer 22) adjacent to each of the plurality of parts 31. Therefore, in the semiconductor light receiving element 1, a PD is formed in the first direction for each of the plurality of parts 31, and a plurality of PDs are also formed and arranged in a distributed manner in a plane intersecting the first direction.

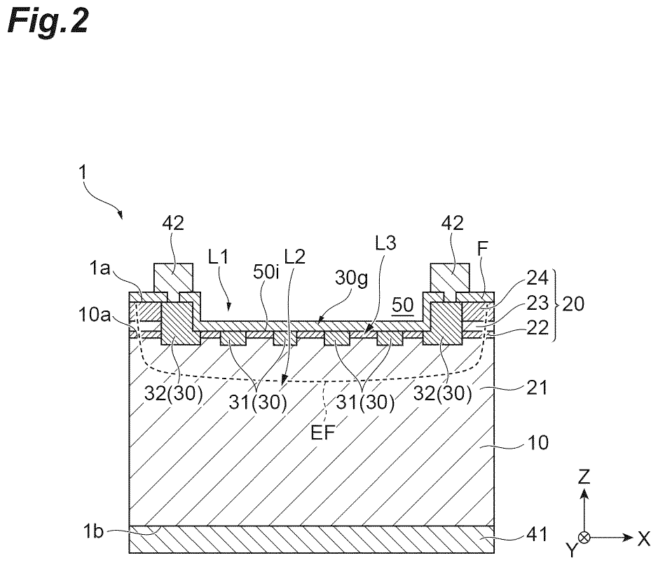

In the semiconductor light receiving element 1 described above, as shown in FIG. 2, when a voltage is applied to the electrodes 41 and 42, an electric field EF is generated in the first semiconductor portion 10 and the second semiconductor portion 20. In this state, when predetermined light L1 is incident on one part 31 of the doped region 30 and is absorbed, the light L1 cannot be extracted as a signal because no electric field is applied to the doped region 30. On the other hand, when another light L2 is not absorbed in the doped region 30 but is absorbed by the light absorption layer 21, the light L2 is extracted as a signal because an electric field is applied.

In addition, when another light L3 is incident between the parts 31 of the doped region 30 (for example, on the gap 30g) and is absorbed by the first cap layer 22, the light L3 is absorbed by the PD formed in a plane intersecting the first direction by the parts 31 and the first cap layer 22 and is extracted as a signal. In addition, when the light L3 is incident between the parts 31 of the doped region 30 and is absorbed by the light absorption layer 21, the light L3 is absorbed by the PD formed in the first direction by the parts 31 and the light absorption layer 21 and is extracted as a signal. Therefore, in the semiconductor light receiving element 1, even light that is absorbed by the first cap layer 22 but has not been extracted as a signal in the past can be extracted as a signal.

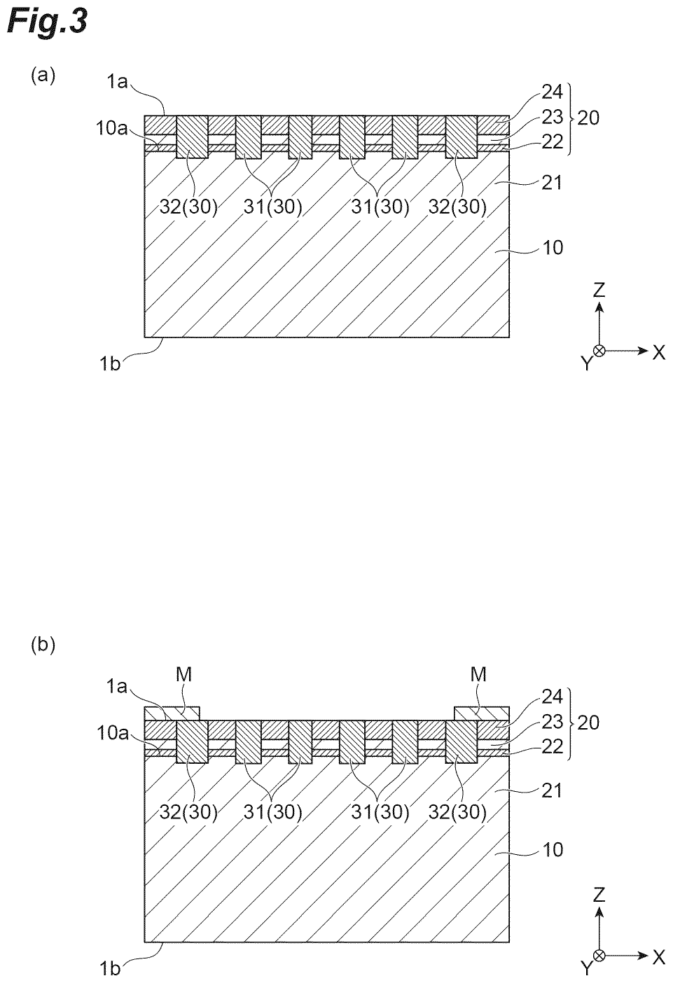

Next, a method for manufacturing the semiconductor light receiving element 1 will be described. FIGS. 3 to 5 are drawings showing a step of the method for manufacturing a semiconductor light receiving element. In this manufacturing method, as shown (a) in FIG. 3, first, the doped region 30 is formed in the first semiconductor portion 10 and the second semiconductor portion 20. When forming the doped region 30 by thermal diffusion, first, a first mask having an opening corresponding to the pattern of the doped region 30 is formed on the front surface 1a of the second semiconductor portion 20, and then impurities are doped to form the doped region 30 in the first semiconductor portion 10 and the second semiconductor portion 20. Thereafter, the first mask is then removed.

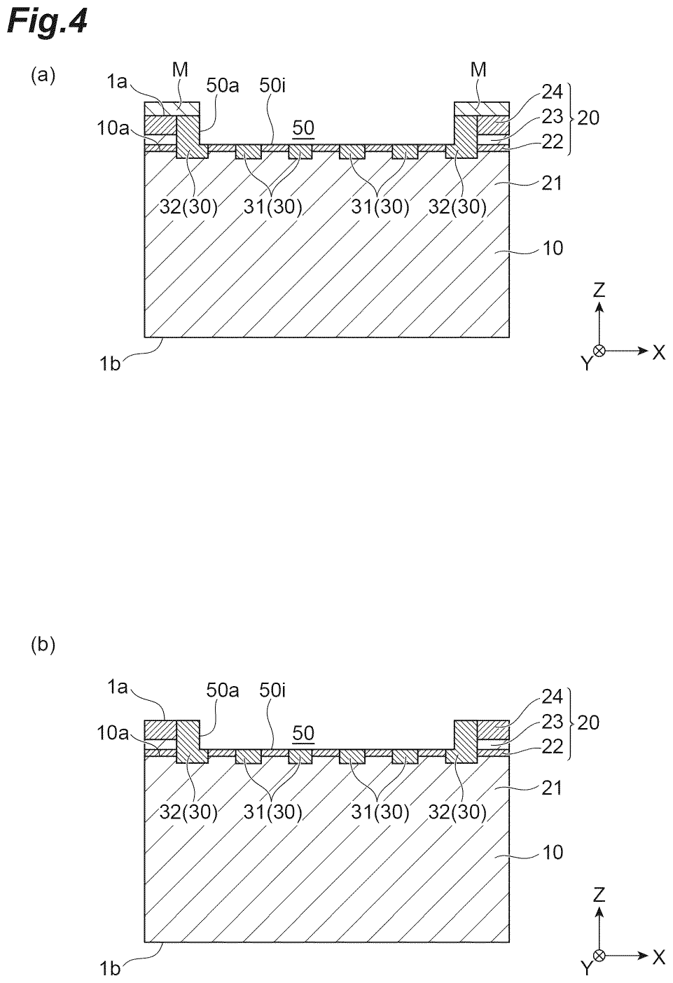

Then, as shown in (b) in FIG. 3, a second mask M for etching is formed on the front surface 1a. Then, as shown in (a) in FIG. 4, the recess 50 is formed on the front surface 1a by etching using the second mask M. More specifically, first, the second cap layer 24 is removed by selective etching using the second mask M. Then, the semiconductor layer 23 is removed by selective etching using the second mask M.

As a result, the recess 50 is formed so that the first cap layer 22 is exposed in a region exposed from the second mask M, and the relatively thin part 31 of the doped region 30 is formed. In addition, in a region covered by the second mask M, the semiconductor layer 23, the second cap layer 24, and a part of the relatively thick outer edge portion 32 of the doped region 30 remain. In this manner, the semiconductor layer 23 can be selectively etched so that only the thin first cap layer 22 remains in the recess 50 as a cap layer on the light absorption layer 21. Thereafter, as shown in (b) in FIG. 4, the second mask M is removed.

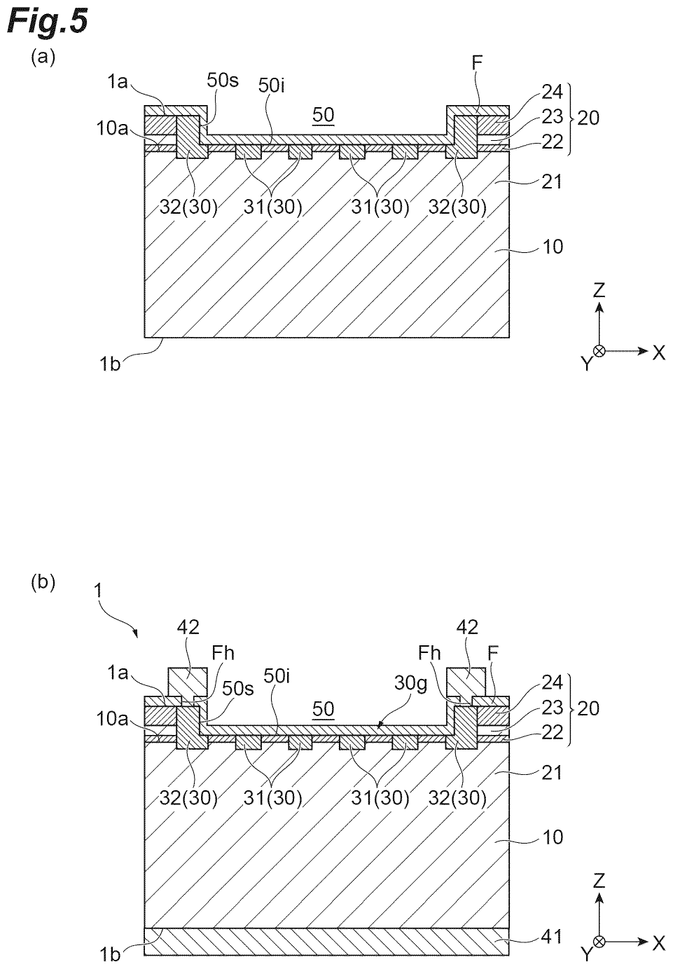

Then, as shown in (a) in FIG. 5, the protective film F is formed so as to cover the front surface 1a, the side surface 50s of the recess 50, and the bottom surface 50i of the recess 50. Thereafter, as shown in (b) in FIG. 5, the through hole Fh is formed in the protective film F, and the electrode 42 is provided so as to be in contact with the doped region 30 through the through hole Fh. At the same time, the electrode 41 is provided on the back surface 1b. As a result, the semiconductor light receiving element 1 is obtained.

As described above, in the semiconductor light receiving element 1, the first cap layer 22 of the first conductivity type having a large band gap energy is stacked on the light absorption layer 21 of the first conductivity type, and the doped region 30 of the second conductivity type is formed on the first cap layer 22 side from the front surface 1a that receives incident light. Then, the doped region 30 includes a plurality of parts 31 facing each other with the gap 30g interposed therebetween when viewed from the first direction intersecting the front surface 1a. For this reason, light incident on the gap 30g of the doped region 30 can be extracted as a signal without being absorbed in the doped region 30. Therefore, the decrease in sensitivity is suppressed. In particular, according to the findings of the present inventors, when the width of the gap 30g is larger than the thickness T22 of the first cap layer 22, the decrease in sensitivity can be further suppressed.

In addition, in the semiconductor light receiving element 1, the plurality of parts 31 of the doped region 30 include at least a pair of first extending portions 31a (and second extending portions 31b (the same hereinbelow)) extending in the same direction when viewed from the first direction, and the width of the gap 30g is a distance between the pair of first extending portions 31a. In this manner, it is possible to easily and reliably configure a structure capable of suppressing a decrease in sensitivity.

In addition, in the semiconductor light receiving element 1, the doped region 30 extends from the first cap layer 22 toward the light absorption layer 21 side and reaches the inside of the light absorption layer 21. In the semiconductor light receiving element 1, the doped region 30 may be configured in this manner.

In addition, the semiconductor light receiving element 1, the recess 50 is formed on the front surface 1a, and the light receiving portion 55 is formed in a region overlapping the bottom surface 50i of the recess 50 when viewed from the first direction. This protects the light receiving portion 55 from contact and makes it less susceptible to damage.

In addition, in the semiconductor light receiving element 1, since the doped region 30 is exposed on the side surface 50s of the recess 50, even light incident on the gap between a part (here, the outer edge portion 32) of the doped region 30 exposed on the side surface 50s of the recess 50 and the part 31 facing the part can be extracted as a signal. As a result, the decrease in sensitivity can be more reliably suppressed. In addition, the doped region 30 includes a part (the above-described relatively thick part of the outer edge portion 32) formed from the side surface 50s of the recess 50 to the top surface (a region that defines the recess 50 at the front surface 1a) of the recess 50. This part has a part, which is thicker and has a higher impurity concentration than the part 31 formed on the bottom surface 50i side of the recess 50 in the doped region 30, on the front surface 1a side. Therefore, it is possible to reduce the contact resistance by making contact with the electrode 42 at this part.

In addition, the semiconductor light receiving element 1 includes the semiconductor layer 23 of the first conductivity type stacked on the first cap layer 22 on the front surface 1a side of the first cap layer 22. Therefore, by using a material having a larger band gap energy than the light absorption layer 21 and the semiconductor layer 23 as the first cap layer 22, it is possible to reduce the dark current and absorption, thereby achieving a further reduction in loss.

In addition, the semiconductor light receiving element 1 includes the second cap layer 24 of the first conductivity type stacked on the semiconductor layer 23 on the front surface 1a side of the semiconductor layer 23. Therefore, since the second cap layer 24 has a function of protecting the semiconductor layer 23, it is possible to select a material of the semiconductor layer 23 that contains a material that is relatively easily oxidized, such as aluminium, thereby improving the freedom of material selection for the semiconductor layer 23.

In the above embodiment, one aspect of the present disclosure has been described. Therefore, the semiconductor light receiving element according to the present disclosure may be any modified version of the semiconductor light receiving element 1 described above. Subsequently, modification examples will be described.

### First Modification Example

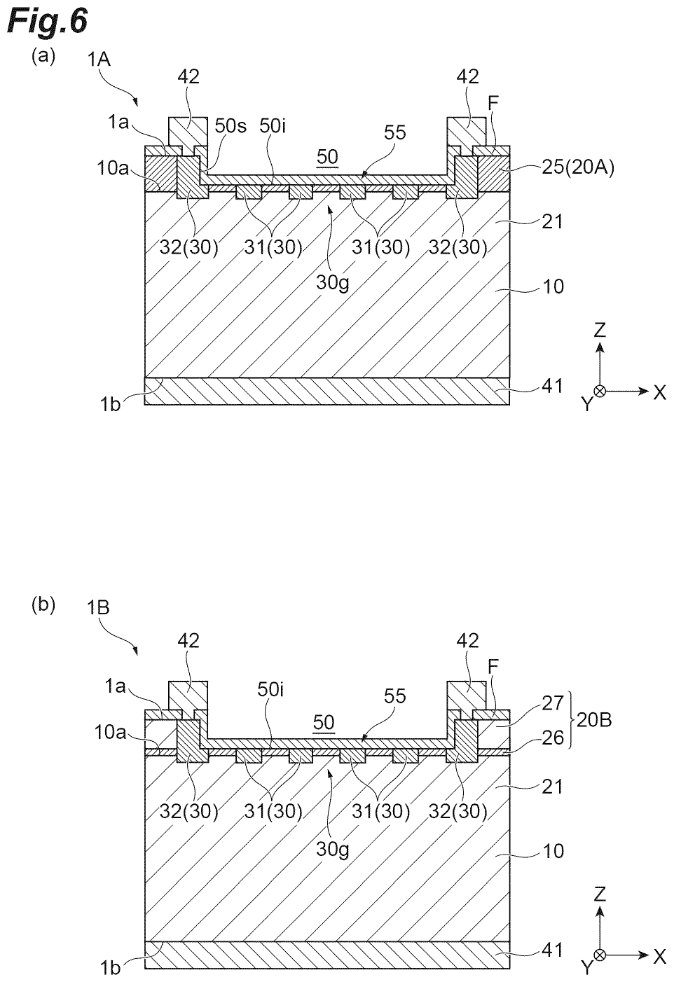

(a) in FIG. 6 is a schematic cross-sectional view showing a semiconductor light receiving element 1A according to a first modification example. The semiconductor light receiving element 1A shown in (a) in FIG. 6 is different from the semiconductor light receiving element 1 in that the semiconductor light receiving element 1A includes a second semiconductor portion 20A instead of the second semiconductor portion 20. The second semiconductor portion 20A is different from the second semiconductor portion 20 in that the second semiconductor portion 20A includes only a single cap layer (second semiconductor layer) 25.

The cap layer 25 is stacked on the light absorption layer 21 on the front surface 1a side of the light absorption layer 21, and has an interface with the light absorption layer 21. The cap layer 25 contains InP (is formed of InP) of the first conductivity type (for example, n-type). Also in the semiconductor light receiving element 1A, the doped region 30 is formed so as to extend from the front surface 1a toward the cap layer 25 side and reach at least the inside of the cap layer 25. More specifically, the doped region 30 extends from the cap layer 25 toward the light absorption layer 21 side and reaches the inside of the light absorption layer 21. Thus, the semiconductor light receiving element 1A does not need to have the semiconductor layer 23 and the second cap layer 24 on the light absorption layer 21. Through such a semiconductor light receiving element 1A as well, the same effects as those of the semiconductor light receiving element 1 are obtained, and the semiconductor stacked structure on the light absorption layer 21 is simplified. In addition, according to the semiconductor light receiving element 1A, etching can be performed even for materials that are difficult to selectively etch by performing the etching with time control or the like. Therefore, it is possible to form thin films regardless of the material. In addition, in this case, the width G30 of the gap 30g can be made larger than the thickness of the relatively thin part of the cap layer 25 located inside the recess 50.

### Second Modification Example

(b) in FIG. 6 is a schematic cross-sectional view showing a semiconductor light receiving element 1B according to a second modification example. The semiconductor light receiving element 1B shown in (b) in FIG. 6 is different from the semiconductor light receiving element 1 in that the semiconductor light receiving element 1B includes a second semiconductor portion 20B instead of the second semiconductor portion 20 and different in the materials of each layer. The second semiconductor portion 20B is different from the second semiconductor portion 20 in that the second semiconductor portion 20B includes a single cap layer (second semiconductor layer) 26 instead of the first cap layer 22 and includes a semiconductor layer (third semiconductor layer) 27 instead of the semiconductor layer 23.

In the semiconductor light receiving element 1B, the material of the first semiconductor portion 10 contains InAsSb. More specifically, in the semiconductor light receiving element 1B, at least the light absorption layer 21 contains InAsSb (is formed of InAsSb) of the first conductivity type (for example, n-type and n⁺-type). The cap layer 26 is stacked on the light absorption layer 21 on the front surface 1a side, and has an interface with the light absorption layer 21. The cap layer 26 contains AlInAsSb (is formed of AlInAsSb) of the first conductivity type (for example, n-type). In addition, the semiconductor layer 27 contains InAsSb (is formed of InAsSb) of the first conductivity type (for example, n-type).

In the semiconductor light receiving element 1B as well, the doped region 30 is formed so as to extend from the front surface 1a toward the cap layer 26 side and reach at least the inside of the cap layer 26. More specifically, the doped region 30 extends from the cap layer 26 toward the light absorption layer 21 side and reaches the inside of the light absorption layer 21. Thus, the semiconductor light receiving element 1B does not need to have the second cap layer 24 on the light absorption layer 21. In this case, the same effects as those of the semiconductor light receiving element 1 are obtained, and the semiconductor stacked structure on the light absorption layer 21 is simplified. Through such a semiconductor light receiving element 1B as well, the same effects as those of the semiconductor light receiving element 1 are obtained, and the semiconductor stacked structure on the light absorption layer 21 is simplified. In addition, according to the semiconductor light receiving element 1B, it is possible to eliminate the cap layer itself when a material that can be selectively etched and has a wide band gap is used. Therefore, since it is possible to reduce loss in the light receiving portion, it is possible to reduce the contact resistance by using a material with a narrow band gap for the contact portion of the cap layer.

### Third Modification Example

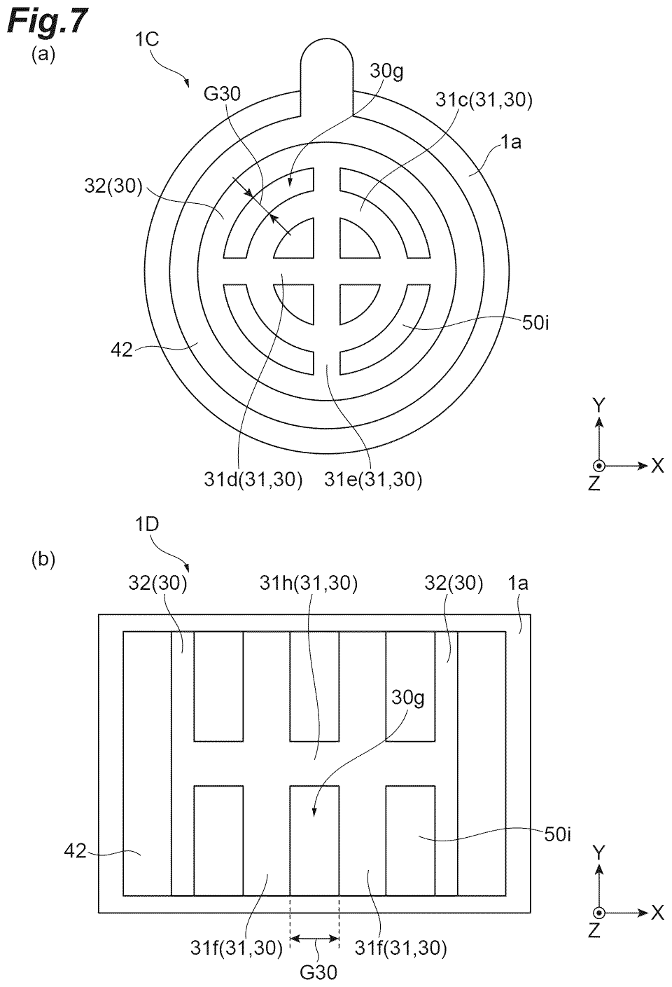

(a) in FIG. 7 is a schematic plan view showing a semiconductor light receiving element 1C according to a third modification example. The semiconductor light receiving element 1C shown in (a) in FIG. 7 is different from the semiconductor light receiving element 1 in the shape of the doped region 30 when viewed from the first direction.

In the semiconductor light receiving element 1C, a plurality of parts 31 of the doped region 30 include a third extending portion 31c that extends in an annular shape when viewed from the first direction. The third extending portion 31c has an annular shape concentric with the outer edge portion 32 when viewed from the first direction. Therefore, the third extending portion 31c and the outer edge portion 32 form a pair of extending portions that extend along the same direction (circumferential direction) herein. Therefore, the gap 30g is formed between the third extending portion 31c and the outer edge portion 32, and at least the width G30 (dimension in the radial direction) of the gap 30g is made larger than the thickness T22 of the first cap layer 22.

In addition, in the semiconductor light receiving element 1C, a plurality of parts 31 of the doped region 30 include a fourth extending portion 31d extending along one direction (here, the X-axis direction) intersecting the first direction and a fifth extending portion 31e extending along another direction (here, the Y-axis direction) intersecting the first direction. The fourth extending portion 31d and the fifth extending portion 31e cross each other. Here, the intersection between the fourth extending portion 31d and the fifth extending portion 31e approximately matches the center of the third extending portion 31c and the outer edge portion 32. The fourth extending portion 31d and the fifth extending portion 31e are connected to the outer edge portion 32 at both ends in the extending direction. In addition, the third extending portion 31c is connected to the fourth extending portion 31d and the fifth extending portion 31e, thereby being connected to the outer edge portion 32 through the fourth extending portion 31d and the fifth extending portion 31e.

The gap between the fourth extending portion 31d and the fifth extending portion 31e, that is, the width of a region surrounded by the fourth extending portion 31d, the fifth extending portion 31e, and the third extending portion 31c differs at each position in a plane intersecting the first direction, but, as an example, its average value may be larger than the thickness T22. Through such a semiconductor light receiving element 1C as well, the same effects as those of the semiconductor light receiving element 1 are obtained. In addition, according to the semiconductor light receiving element 1C, it is possible to easily design a gap (gap 30g) even in a circular shape, and it is possible to design in such a manner that the relationship between the doped region 30 and the gap can be maximized depending on the combination.

### Fourth Modification Example

(b) in FIG. 7 is a schematic plan view showing a semiconductor light receiving element 1D according to a fourth modification example. The semiconductor light receiving element 1D shown in (b) in FIG. 7 is different from the semiconductor light receiving element 1 in that the semiconductor light receiving element 1D has a rectangular outer shape when viewed from the first direction and in the shape of the doped region 30 when viewed from the first direction.

In the semiconductor light receiving element 1D, a plurality of parts 31 of the doped region 30 include a pair of sixth extending portions 31f that extend along one direction (here, the Y-axis direction) intersecting the first direction. The sixth extending portions 31f extend in the same direction. Therefore, the gap 30g is formed between the sixth extending portions 31f, and at least the width G30 of the gap 30g is made larger than the thickness T22 of the first cap layer 22. In addition, in the semiconductor light receiving element 1D, a pair of outer edge portions 32 also extend in the same direction as the sixth extending portion 31f. Therefore, the gap between one outer edge portion 32 and the sixth extending portion 31f adjacent to the one outer edge portion 32 may be set as the gap 30g, which is larger than the thickness T22.

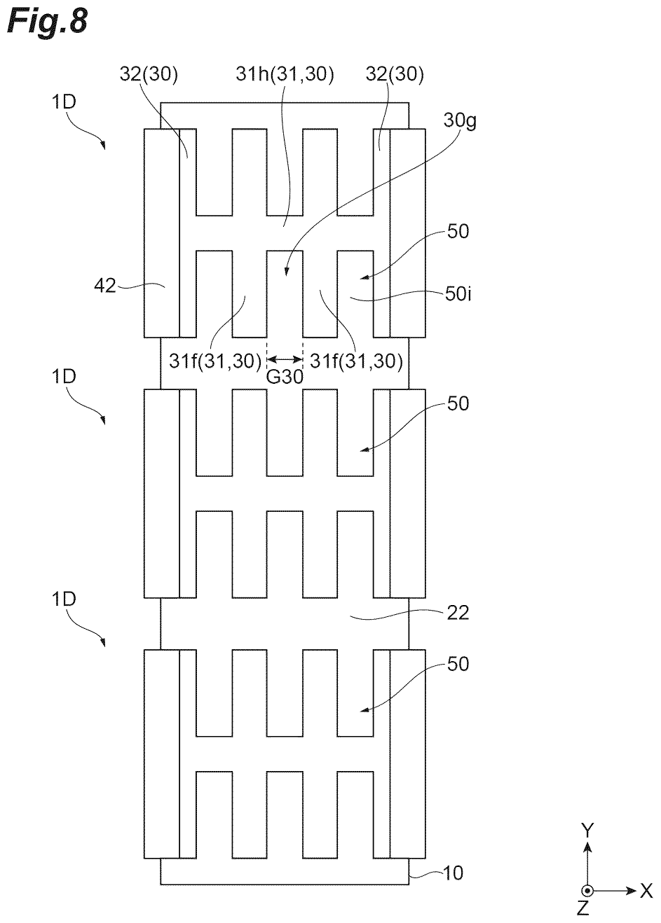

In addition, in the semiconductor light receiving element 1D, the doped region 30 includes a single seventh extending portion 31h that extends along another direction (here, the X-axis direction). The seventh extending portion 31h is connected to the outer edge portion 32 at both ends in the extending direction. The sixth extending portion 31f is connected to the seventh extending portion 31h, thereby being connected to the outer edge portion 32 through the seventh extending portion 31h. Through such a semiconductor light receiving element 1D as well, the same effects as those of the semiconductor light receiving element 1 are obtained. In addition, in the semiconductor light receiving element 1D, as shown in FIG. 8, a plurality of semiconductor light receiving elements 1D can be easily arranged in an array.

As shown in FIG. 8, when forming a structure in which a plurality of semiconductor light receiving elements 1D are arranged in an array, as an example, when forming the recess 50 as shown in FIG. 4 after forming the doped region 30 as shown in FIG. 3 at a position corresponding to each of the semiconductor light receiving elements 1D, etching can be performed simultaneously over the plurality of semiconductor light receiving elements 1D (that is, it is not necessary to arrange the second mask M between the semiconductor light receiving elements 1D adjacent to each other). In addition, the recesses 50 facing each other are integrally formed between the semiconductor light receiving elements 1D adjacent to each other. In addition, in FIG. 8, the protective film F is not shown, and the bottom surface 50i of the recess 50 (the front surface of the first cap layer 22) is shown.

On the other hand, when performing etching to form the recesses 50, the second mask M may be provided between the semiconductor light receiving elements 1D adjacent to each other, so that the recesses 50 are formed individually between the plurality of semiconductor light receiving elements 1D. In this case, between the semiconductor light receiving elements 1D adjacent to each other, the recesses 50 facing each other are spaced apart from each other by the front surface 1a (a relatively thick part of the second semiconductor portion 20) that remains unetched therebetween.

### OTHER MODIFICATION EXAMPLES

Although the embodiment and a plurality of modification examples have been described above, the semiconductor light receiving element according to the present disclosure is not limited to the above-described semiconductor light receiving elements 1 to 1D, and further modifications can be applied. For example, in the above-described embodiment and modification examples, the material of the light absorption layer 21 is not limited to InGaAs and InAsSb, but various other semiconductors containing In, P, Al, As, Sb, and Ga, such as InAs, GaAs, GaN, and InGaN, can be used.

In addition, the materials or the first cap layer 22, the second cap layer 24, and the cap layers 25 and 26 are not limited to InP and AlInAsSb, but various other semiconductors containing In, P, Al, As, Sb, and G, such as InAsP, AlInP, AllnAsP, InPSb, and GaN, can be used.

In addition, in the above embodiment, the case where the doped region 30 reaches the inside of the light absorption layer 21 has been described, but the doped region 30 may not reach the inside of the light absorption layer 21.

In addition, in the semiconductor light receiving element 1C according to the third modification example, the doped region 30 may include a plurality of third extending portions 31c having different diameters (concentric third extending portions 31c), and the gap 30g larger than the thickness T22 may be defined between these. In addition, in the semiconductor light receiving element 1C, an undoped region (in other words, a region other than the doped region 30 (the same hereinbelow)) may be provided so as to divide the annular third extending portion 31c and the outer edge portion 32 into a plurality of arc-shaped parts. In this case, as an example, the third extending portion 31c and the outer edge portion 32 may be equally divided into four arc-shaped parts by providing one undoped linear region extending onto the fourth extending portion 31d and another undoped linear region extending onto the fifth extending portion 31e.

In addition, in the semiconductor light receiving element 1D according to the fourth modification example, the doped region 30 may include three or more sixth extending portions 31f, or the number of sixth extending portions 31f may be one. When the number of sixth extending portion 31f is one, the gap 30g may be formed between the sixth extending portion 31f and the outer edge portion 32, and the width of the gap 30g may be made larger than the thickness T22. In addition, in the semiconductor light receiving element 1D, the doped region 30 may not include the sixth extending portion 31f. In this case, the gap between a pair of outer edge portions 32 may be defined as the gap 30g, and the width of the gap 30g may be set to be larger than thickness T22. In addition, in the semiconductor light receiving element 1D, the doped region 30 may include two or more seventh extending portions 31h. In addition, in the semiconductor light receiving element 1D, only one outer edge portion 32 may be provided.

Then, in the semiconductor light receiving element 1D, various modifications including those described above can be applied in any combination, and in that case, the positions of the sixth extending portion 31f and the seventh extending portion 31h can also be set arbitrarily. For example, when the doped region 30 of the semiconductor light receiving element 1D does not include the sixth extending portion 31f but includes two seventh extending portions 31h, the two seventh extending portions 31h may be arranged so as to connect their ends in the extending direction (here, the Y-axis direction) of the outer edge portion 32 to each other, so that, as a whole, the doped region 30 has a rectangular ring shape when viewed from the first direction. Alternatively, when the sixth extending portion 31f is not included but one seventh extending portion 31h is included, the one seventh extending portion 31h may be arranged so as to connect their centers in the extending direction (here, the Y-axis direction) of the outer edge portion 32, so that, as a whole, the doped region 30 has an H shape when viewed from the first direction.

In addition, the configuration of each of the semiconductor light receiving elements 1 to 1D can be partially replaced for use. For example, the pattern of the doped region 30 in the semiconductor light receiving elements 1C and 1D may be adopted as the doped region 30 in the semiconductor light receiving element 1A or the semiconductor light receiving element 1B.

### REFERENCE SIGNS LIST

1, 1A, 1B, 1C, 1D: semiconductor light receiving element, 1a: front surface, 21: light absorption layer (first semiconductor layer), 22: first cap layer (second semiconductor layer), 23, 27: semiconductor layer (third semiconductor layer), 24: second cap layer (fourth semiconductor layer), 25, 26: cap layer (second semiconductor layer), 30: doped region, 30g: gap, 31: part, 31a: first extending portion (extending portion), 31b: second extending portion (extending portion), 31c: third extending portion (extending portion), 31f: sixth extending portion (extending portion), 50: recess, 50i: bottom surface, 50s: side surface, 55: light receiving portion.

1. A semiconductor light receiving element, comprising:
a front surface that receives incident light;
a first semiconductor layer of a first conductivity type;
a second semiconductor layer of the first conductivity type stacked on the first semiconductor layer on the front surface side of the first semiconductor layer and having a band gap energy larger than a band gap energy of the first semiconductor layer; and
a doped region formed so as to extend from the front surface toward the second semiconductor layer side and reach at least an inside of the second semiconductor layer and having a second conductivity type different from the first conductivity type,
wherein a thickness of the second semiconductor layer in a first direction intersecting the front surface is smaller than a thickness of the first semiconductor layer in the first direction,
the doped region includes a plurality of parts facing each other with a gap interposed therebetween when viewed from the first direction, and
a width of the gap is larger than a thickness of the second semiconductor layer in the first direction.

2. The semiconductor light receiving element according to claim 1,
wherein the plurality of parts of the doped region include at least a pair of extending portions extending in the same direction when viewed from the first direction, and
the width of the gap is a distance between the pair of extending portions.

3. The semiconductor light receiving element according to claim 1,
wherein the doped region extends from the second semiconductor layer toward the first semiconductor layer side and reaches an inside of the first semiconductor layer.

4. The semiconductor light receiving element according to claim 1,
wherein a recess is formed on the front surface, and
a light receiving portion is formed in a region overlapping a bottom surface of the recess when viewed from the first direction.

5. The semiconductor light receiving element according to claim 4,
wherein the doped region is exposed on a side surface of the recess.

6. The semiconductor light receiving element according to claim 1, further comprising:
a third semiconductor layer of the first conductivity type stacked on the second semiconductor layer on the front surface side of the second semiconductor layer.

7. The semiconductor light receiving element according to claim 6, further comprising:
a fourth semiconductor layer of the first conductivity type stacked on the third semiconductor layer on the front surface side of the third semiconductor layer.

8. The semiconductor light receiving element according to claim 1,
wherein the first semiconductor layer contains InGaAs, and
the second semiconductor layer contains InP or InAsP.

9. The semiconductor light receiving element according to claim 6,
wherein the first semiconductor layer contains InAsSb or InAs,
the second semiconductor layer contains AlInAsSb, and
the third semiconductor layer contains InAsSb or InPSb.

10. The semiconductor light receiving element according to claim 7,
wherein the first semiconductor layer contains InGaAs,
the second semiconductor layer contains InP or InAsP,
the third semiconductor layer contains InGaAs, and
the fourth semiconductor layer contains InP or InAsP.
